(19) United States
(12) Patent Application Publication
(10) Pub. No.: US 2017/0365395 A1
(43) Pub. Date: Dec. 21, 2017

(54) 3D SPIRAL INDUCTOR

(71) Applicant: Dyi-Chung HU, Hsinchu (TW)

(72) Inventor: Dyi-Chung HU, Hsinchu (TW)

(21) Appl. No.: 15/481,605

(22) Filed: Apr. 7, 2017

Related U.S. Application Data
(60) Provisional application No. 62/351,362, filed on Jun. 17, 2016.

(51) Int. Cl. H01F 27/28; H01L 21/48; H01F 41/04; H01L 49/02; H01F 27/24

(52) U.S. Cl. CPC H01F 27/2804; H01L 28/10; H01F 27/24; H01F 41/041; H01L 21/486

(57) ABSTRACT

A miniaturized 3D spiral inductor is disclosed. The 3D spiral inductor, comprising: a plurality of top metal wires configured in parallel on a top surface of a dielectric layer; a plurality of metal vias formed in a matrix of 2×N, and coelevationally embedded in the dielectric layer; each top metal wire electrically coupled top ends of a left metal via and a right metal via; and a plurality of bottom metal wires configured on a bottom ends of the plurality of metal vias; each bottom metal wire electrically coupled bottom ends of a left metal via and a right metal via; the plurality of metal elements connected sequentially to form a 3D spiral inductor.

### BACKGROUND

### Technical Field

The present invention relates to a 3D spiral inductor, especially relates to a miniaturized 3D spiral inductor embedded in a dielectric layer.

### Description of Related Art

FIG. 1 shows a prior art

FIG. 1 is US 2015/0303888 A1, which shows a schematic view of a semiconductor device with an LC resonant circuit, which includes an insulation layer 110, an inductor component 130, and a capacitor component 150. The inductor component 130 and the capacitor component 150 are formed by patterning two metal layers located on two opposite surfaces of the first insulation layer 110. The inductor component 130 and the capacitor component 150 are electrically coupled with each other through vias 194.

The disadvantage for the prior art is that it disclosed a flat inductor. A size of the planar inductor is limited due to its winding on a flat surface. Further, the diameter of each winding is smaller and smaller due to its snail winding on a flat surface. A size-flexible spiral inductor needs to be developed for matching various design choice.

### BRIEF DESCRIPTION OF THE DRAWINGS

FIG. 1 shows a prior art.

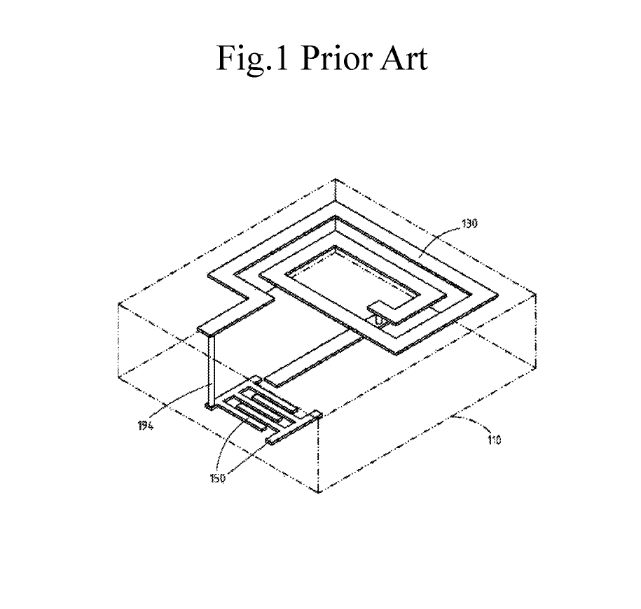

FIGS. 2A˜2E show different views for a first embodiment according to the present invention.

FIG. 3 shows an inductor equivalent to the first embodiment.

FIGS. 4A˜4E show a second embodiment according to the present invention.

FIG. 5 shows an inductor equivalent to the second embodiment.

FIGS. 6A˜6D show a fabrication process for making a 3D spiral inductor of the first embodiment.

FIGS. 7A˜7F show a fabrication process for making a 3D spiral inductor of the second embodiment.

### DETAILED DESCRIPTION OF THE INVENTION

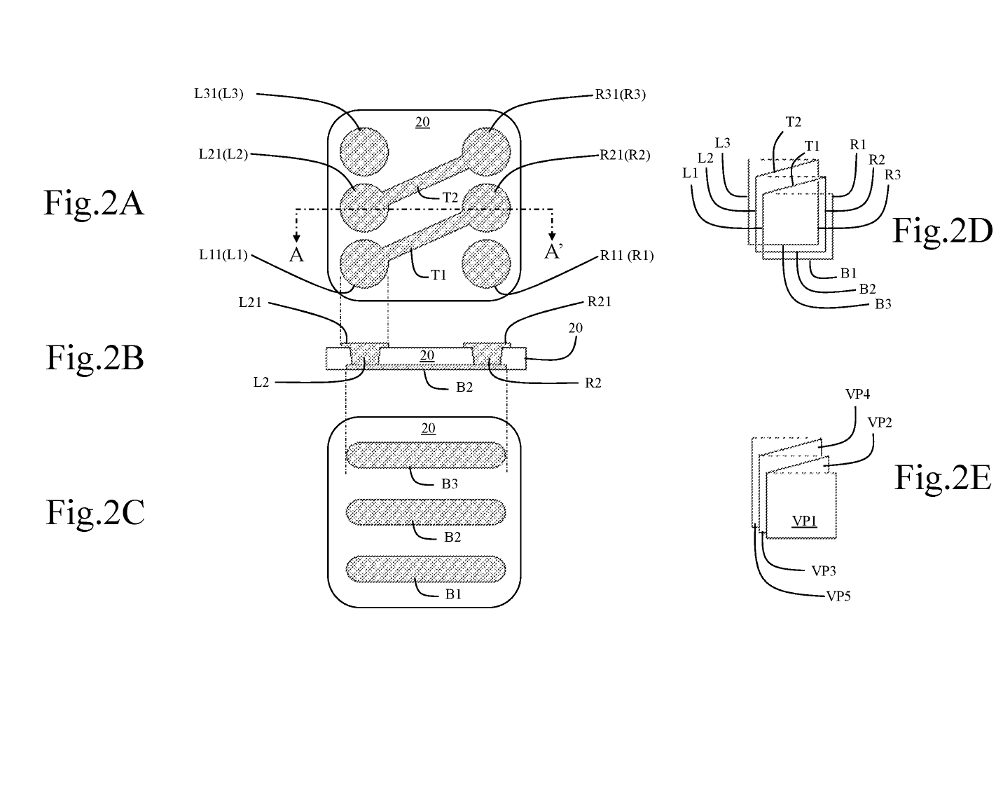

FIGS. 2A˜2E show different views for a first embodiment according to the present invention.

FIG. 2A shows a top view of the first embodiment.

FIG. 2A shows a top view of an inductor which comprises a plurality of top metal pads in a matrix of 2×N. FIG. 2A shows the top metal pads being in a matrix of 2×3, as an example, formed on a top surface of a dielectric layer 20. The matrix comprises a plurality of left metal pads L11, L21, L31 and a plurality of right metal pads R11, R21, R31.

A plurality of top metal wires T1, T2 . . . , configured in parallel and diagonally. The top first metal wire T1 connects left first metal pads L11 and right second metal pad R21. A top second metal wire T2 connects the left second metal pad L21 and right third metal pad R31.

The right first metal pad R11 functions as a first terminal of the inductor, and the left third metal pad L31 functions as a second terminal of the inductor.

FIG. 2B shows a section view of FIG. 2A according to line AA′.

FIG. 2B shows a plurality of left metal vias L1, L2, L3, and a plurality of right metal vias R1, R2, R3.

Both the left metal vias and the right metal visa are all coelevationally embedded in the same dielectric layer 20. Each metal via L1, L2, L3, R1, R2, R3 has the corresponding top metal pad L11, L21, L31, R11, R21, R31 respectively configured on its top.

FIG. 2B shows a bottom second metal wire B2 electrically coupled to bottom ends of the left second metal via L2 and the right second metal via R2.

FIG. 2C shows a bottom view of the first embodiment.

FIG. 2C shows a plurality of bottom metal wires B1, B2, B3 configured in parallel and latitudinally. The plurality of bottom metal wires B1, B2, B3 are embedded in the dielectric layer 20.

The bottom first metal wire B1 is electrically coupled to bottom ends of the left first metal via L1 and the right first metal via R1.

The bottom second metal wire B2 is electrically coupled to bottom ends of the left second metal via L2 and the right second metal via R2.

The bottom third metal wire B3 is electrically coupled to bottom ends of the left third metal via L3 and right third metal via R3.

FIG. 2D shows a 3D spiral inductor for the first embodiment according to the present invention.

FIG. 2D shows a 3D spiral inductor for the first embodiment, referring to FIGS. 2A-2C, the 3D spiral inductor is further drawn as shown in FIG. 2D in a 3D view without showing dielectric layer 20. In other words, FIG. 2D is a perspective view of the first embodiment according to the present invention.

FIG. 2D shows a 3D spiral inductor formed by a connection of metal elements R1-B1-L1-T1-R2-B2-L2-T2-R3-B3-L3 in a 3D view.

FIG. 2E shows virtual planes VP1˜VP5.

FIG. 2E shows virtual planes VP1˜VP5 to assist describing the structure of the first embodiment. The right first metal via R1, bottom first metal B1, and left first metal via L1 are configured coplanarly in a first virtual plane VP1.

The left first metal via L1, top first metal wire T1, and right second metal via R2 are configured coplanarly in a second virtual plane VP2.

The right second metal via R2, bottom second metal wire B2, and left second metal via L2 are configured coplanarly in a third virtual plane VP3.

The left second metal via L2, top second metal wire T2, and right third metal via R3 are configured coplanarly in a fourth virtual plane VP4.

The right third metal via R3, bottom third metal wire B3, and left third metal via L3 are configured coplanarly in a fifth virtual plane VP5.

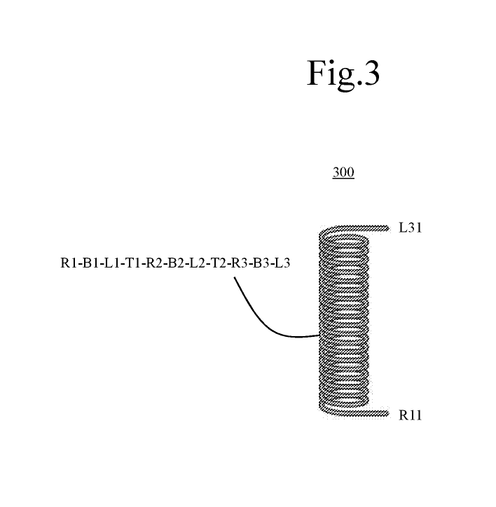

FIG. 3 shows an inductor equivalent to the first embodiment.

FIG. 3 shows a traditional discrete 3D spiral inductor 300 which is theoretically equivalent to the first embodiment, the top end of the 3D spiral inductor 300 is a first terminal equivalent to left third metal pad L31 of the first embodiment (FIG. 2A). The bottom end of the 3D spiral inductor 300 is a second terminal equivalent to right first metal pad R11 of the first embodiment (FIG. 2A). The 3D spiral inductor is now miniaturized and realized by metal elements R1-B1-L1-T1-R2-B2-L2-T2-R3-B3-L3 embedded in the dielectric layer 20 according to the first embodiment according to the present invention.

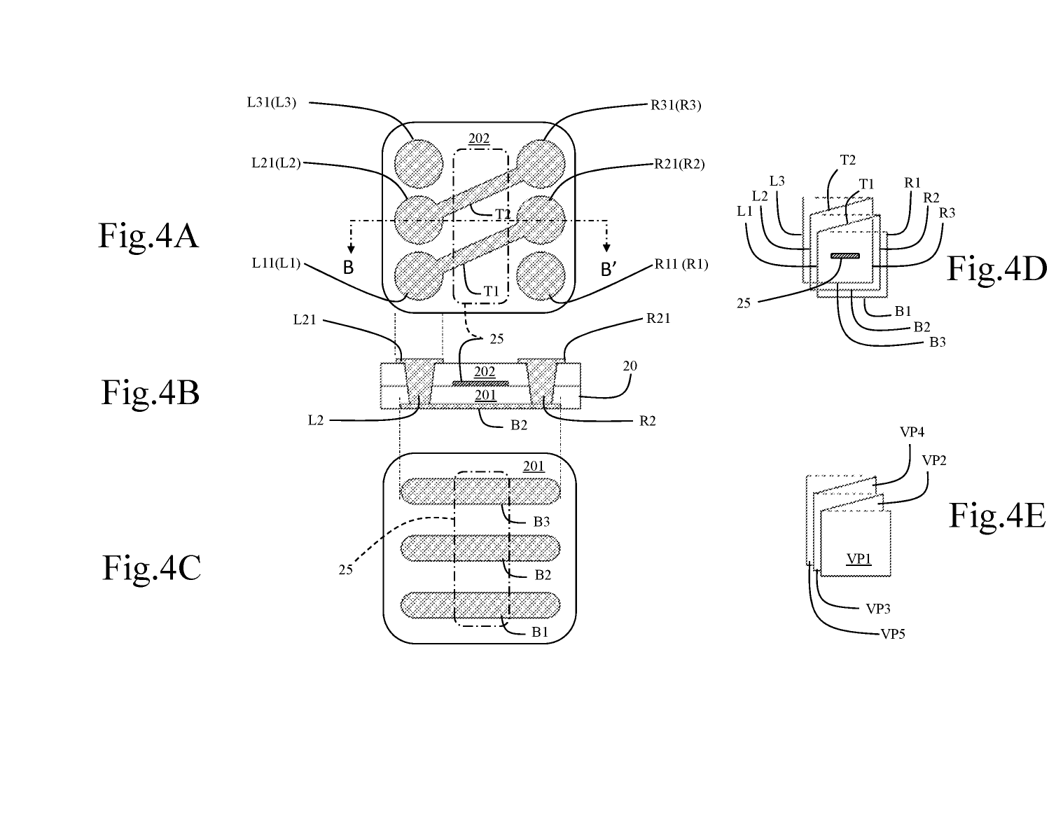

FIGS. 4A˜4E show a second embodiment according to the present invention.

FIG. 4A shows a top view of the second embodiment.

FIG. 4A is the same as FIG. 2A, and is therefore omitted to describe for simplification of the specification.

FIG. 4B shows a section view of FIG. 4A according to line BB′.

FIG. 4B shows a magnetic core 25 extended along a center axis of the 3D spiral inductor. The dielectric layer comprising a top section dielectric layer 202 and a bottom section dielectric layer 201. The magnetic core 25 is configured on a top surface of the bottom section 201 of the dielectric layer.

FIG. 4C shows a bottom view of the second embodiment.

FIG. 4C is the same as FIG. 2C and is therefore omitted to describe for simplification of the specification.

FIG. 4D shows a 3D spiral inductor for the second embodiment according to the present invention.

FIG. 4D shows a magnetic core 25 extended along a center axis of the 3D spiral inductor. FIG. 4D shows a 3D spiral inductor of the second embodiment formed in a 3D view without showing dielectric layer 20. In other words, FIG. 4D is a perspective view of the second embodiment according to the present invention.

FIG. 4D shows a 3D spiral inductor formed by a connection of metal elements R1-B1-L1-T1-R2-B2-L2-T2-R3-B3-L3 in a 3D view.

FIG. 4E shows virtual planes VP1˜VP5.

FIG. 4E is the same as FIG. 2E, and is therefore omitted to describe for simplification of the specification.

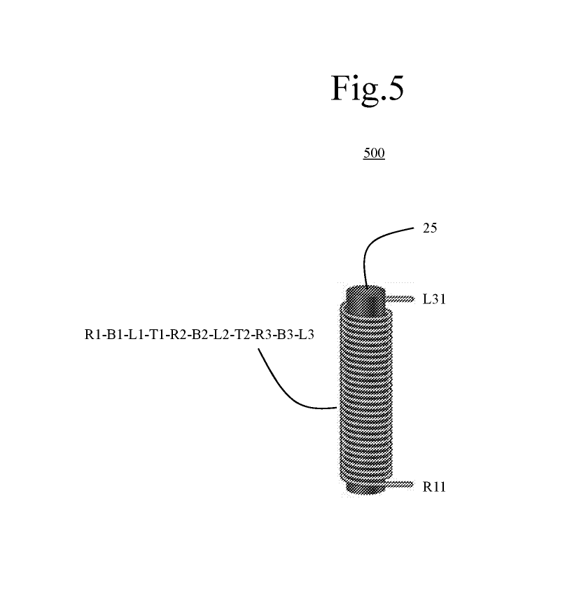

FIG. 5 shows an inductor equivalent to the second embodiment.

FIG. 5 shows a traditional discrete magnetic cored 3D spiral inductor 500 which is theoretically equivalent to the second embodiment, the top end of the 3D spiral inductor 500 is a first terminal equivalent to left third metal pad L31 of the second embodiment (FIG. 4A). The bottom end of the 3D spiral inductor 500 is a second terminal equivalent to right first metal pad R11 of the second embodiment (FIG. 4A). The centered black magnetic core is equivalent to the magnetic core 25 of the second embodiment (FIG. 4A). The 3D spiral inductor is now miniaturized and realized by metal elements R1-B1-L1-T1-R2-B2-L2-T2-R3-B3-L3 embedded in the dielectric layers 201, 202 according to the second embodiment (FIG. 4B).

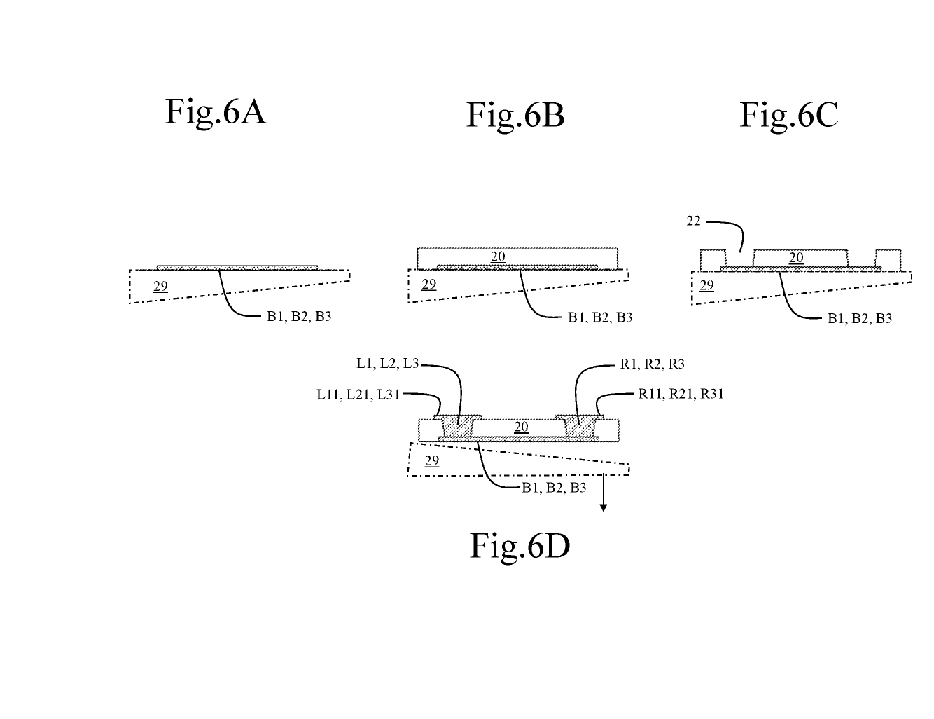

FIGS. 6A˜6D show a fabrication process for making a 3D spiral inductor of the first embodiment.

FIG. 6A shows:

preparing a temporary carrier 29 with a release layer (not shown) on top surface of the temporary carrier 29;

forming a plurality of bottom metal wires B1, B2, B3 on top of the release layer (not shown);

FIG. 6B shows:

forming a dielectric layer 20 on a top side of the plurality of bottom metal wires B1˜B3;

FIG. 6C shows:

etching the dielectric layer 20 to form a plurality of vias 22 in a matrix of 2×N;

FIG. 6D shows:

filling metal in each via 22 to form a plurality of metal vias L1˜L3, R1˜R3, forming a plurality of metal pads L11, L21, L31, R11, R21, R31 and forming a plurality of top metal wires T1, T2 on a top surface of the dielectric layer 20; each metal pad is configured on a top end of each corresponding metal via L1-L3, R1-R3; and detaching the temporary carrier 29.

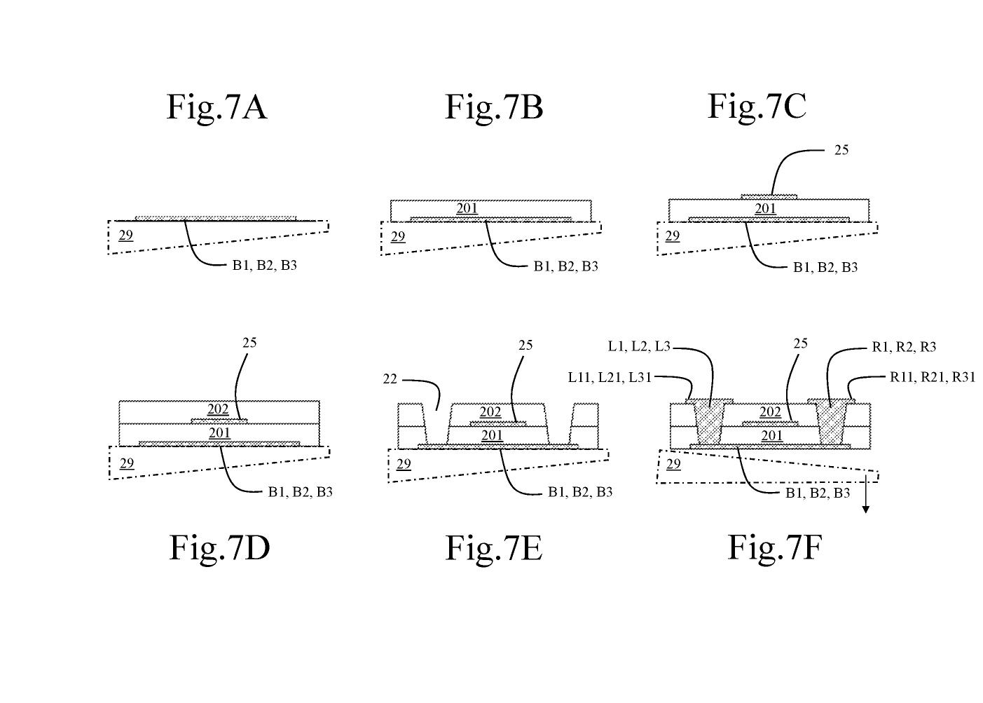

FIGS. 7A˜7F show a fabrication process for making a 3D spiral inductor of the second embodiment.

FIG. 7A shows:

preparing a temporary carrier 29 with a release layer (not shown) on top surface of the temporary carrier 29;

forming a plurality of bottom metal wires B1, B2, B3 on top of the release layer (not shown);

FIG. 7B shows:

forming a first dielectric layer 201 on a top side of the plurality of bottom metal wires B1˜B3;

FIG. 7C shows:

forming a magnetic core 25 on a top side of the first dielectric layer 201;

FIG. 7D shows:

forming a second dielectric layer 202 on a top side of the magnetic core 25;

FIG. 7E shows:

etching the first dielectric layer 201 and second dielectric layer 202 to form a plurality of vias 22 in a matrix of 2×N;

FIG. 7F shows:

filling metal in each via 22 to form a plurality of metal vias L1˜L3, R1˜R3; forming a plurality of metal pads L11, L21, L31, R11, R21, R31 and forming a plurality of top metal wires T1, T2 on a top surface of the dielectric layer 20; each metal pad is configured on a top end of each corresponding metal via L1˜L3, R1˜R3; and detaching the temporary carrier 29.

While several embodiments have been described by way of example, it will be apparent to those skilled in the art that various modifications may be configured without departs from the spirit of the present invention. Such modifications are all within the scope of the present invention, as defined by the appended claims.

### NUMERICAL SYSTEM

dielectric layer 20, 201, 202
magnetic core 25
spiral inductor 300, 500
bottom metal wires B1, B2, B3
left metal via L1, L2, L3
left metal pads L11, L21, L31
right metal via R1, R2, R3
right metal pads R11, R21, R31
top metal wires T1, T2
virtual plane VP1~VP5

What is claimed is:

1. A 3D spiral inductor, comprising:
a plurality of top metal wires, configured in parallel on a top surface of a dielectric layer;
a plurality of metal vias, formed in a matrix of 2×N, and coelevationally embedded in the dielectric layer; each top metal wire electrically coupled top ends of a left metal via and a right metal via; and
a plurality of bottom metal wires, configured on a bottom ends of the plurality of metal vias; each bottom metal wire electrically coupled bottom ends of a left metal via and a right metal via; the plurality of metal elements connected sequentially to form a 3D spiral inductor.

2. A 3D spiral inductor as claimed in claim 1, further comprising:
a magnetic core extended along a center axis of the 3D spiral inductor.

3. A 3D spiral inductor as claimed in claim 2, wherein the dielectric layer comprising a top section and a bottom section, the magnetic core configured on a top surface of the bottom section of the dielectric layer.

4. A fabrication process for making a 3D spiral inductor, comprising:
forming a plurality of bottom metal wires;
forming a dielectric layer on a top side of the plurality of bottom metal wires;
etching the dielectric layer to form a plurality of vias in a matrix of 2×N; and
filling metal in each via and forming a contact pad on a top end of a corresponding metal via.

5. A fabrication process for making a 3D spiral inductor, comprising:
forming a plurality of bottom metal wires;
forming a bottom dielectric layer on a top side of the plurality of bottom metal wires;
forming a magnetic core on a top side of the bottom dielectric layer;
etching the first and second dielectric layer to form a plurality of vias in a matrix of 2×N; and
filling metal in each via and forming a contact pad on a top end of a corresponding metal via.
